(19) United States
(12) Patent Application Publication
(10) Pub. No.: US 2026/0282257 A1
(43) Pub. Date: Sep. 17, 2026

(54) GROUND SUPPORT SYSTEM FOR LED DISPLAYS

(71) Applicant: Fred Lyuber, Winter Garden, FL (US)

(72) Inventor: Fred Lyuber, Winter Garden, FL (US)

(21) Appl. No.: 19/076,700

(22) Filed: Mar. 11, 2025

(51) Int. Cl. H05K 5/02; F16M 11/24; H05K 5/30

(52) U.S. Cl. CPC H05K 5/0234; F16M 11/24; H05K 5/30

(57) ABSTRACT

A ground support device includes a panel having a pair of raised walls along the top surface and a series of threaded receptacles along each corner. Each of the threaded receptacles include a hole and a hollow threaded sleeve for receiving an elongated threaded leg. Each leg having a shaped head along a top end and a base plate along a bottom end. Each of the legs are independently rotated within the threaded receptacle to raise and lower one corner of the panel. A ground support system includes a support beam that is suspended across a plurality of ground support devices for supporting a plurality of LED screens to form a large-screen LED display. The height of each ground support device is adjustable underload without removing the individual LED screens from the support beam.

### TECHNICAL FIELD

The present invention relates generally to the field of light-emitting diode (LED) display screens, and more particularly to a ground support system for use in assembling a large-screen LED display.

### BACKGROUND

The statements in this section merely provide background information related to the present disclosure and may not constitute prior art.

A large-screen LED display is essentially a plurality of individual LED screens that are stacked in sequence and electrically connected together to form the display. Constructing large-screen LED displays is a long and complicated process that typically requires multiple professional installers and incurs high labor costs.

Because each individual screen forms a part of the overall picture shown by the display, it is critical that each of the LED screens be aligned and positioned completely level to each other. In this regard, if even one screen is out of level by a few millimeters, the picture/text on the large-screen display will not be aligned and will be immediately noticeable to those viewing the display. As such, it is important that installers correctly align and connect the screens onto ground and vertical support structures to form the completed display.

Although there are many known ground support structures onto which display screens can be positioned, such structures do not allow installers to make height adjustments once they have begun bearing weight. As such, the installer must ensure the support structure is completely level prior to beginning to stack the individual LED screens onto the ground support structure.

Unfortunately, it is not uncommon for a portion of the ground support structure to shift during the installation process. In many cases, this shifting occurs due to compression of the ground or carpet beneath the display, resulting in one or more individual LED screens becoming misaligned with the neighboring screens. When this occurs, the installers must disassemble and remove all of the screens from the affected portion of the ground support structure, adjust the height of the structure, and then restack the screens. This may happen multiple times before the resulting display is level. Such a feature is a major contributor to the high installation costs for assembling large screen displays.

The present invention, directed to a ground support system for LED displays, differs from the conventional art in a number of aspects. The manner by which will become more apparent in the description which follows, particularly when read in conjunction with the accompanying drawings.

### SUMMARY OF THE INVENTION

The present invention is directed to a ground support device and system for LED displays. One embodiment of the present invention can include a generally flat panel having a top surface, a bottom surface and a plurality of sides that form a generally square-shaped main body. A pair of raised walls can be positioned along the top surface of the panel, and a series of threaded receptacles can be positioned along the panel adjacent to each corner. Each of the threaded receptacles can include a hole along the top surface of the panel, and a hollow threaded sleeve that is positioned along the bottom surface of the panel directly beneath the hole.

In one embodiment, a plurality of elongated threaded legs are provided such that one leg is located within each of the threaded receptacles. Each of the legs can include a shaped head along a top end and a base plate along a bottom end. Each of the legs can be independently rotated within the threaded receptacle to selectively raise or lower the corner of the panel to which the leg is secured.

In one embodiment, a plurality of ground support devices can be positioned such that the raised walls form a continuous channel for receiving and suspending a support beam along the plurality of ground support devices to form a ground support system. When so positioned, any number of individual LED screens can be positioned onto the support beam to form a large-screen LED display.

In one embodiment, adjustments to the height of each of the ground support devices can be made under load without removing the individual LED screens from the support beam.

This summary is provided merely to introduce certain concepts and not to identify key or essential features of the claimed subject matter.

### BRIEF DESCRIPTION OF THE DRAWINGS

Presently preferred embodiments are shown in the drawings. It should be appreciated, however, that the invention is not limited to the precise arrangements and instrumentalities shown.

FIG. 1 is a perspective view of a ground support device of the ground support system, in accordance with one embodiment of the invention.

FIG. 2A is a side view of the ground support system in operation, in accordance with one embodiment of the invention.

FIG. 2B is a front view of the ground support system in operation, in accordance with one embodiment of the invention.

FIG. 3 is a perspective view of a ground support device of the ground support system, in accordance with one embodiment of the invention.

FIG. 4A is a side view of the ground support system in operation, in accordance with one embodiment of the invention.

FIG. 4B is a front view of the ground support system in operation, in accordance with one embodiment of the invention.

### DETAILED DESCRIPTION OF THE INVENTION

While the specification concludes with claims defining the features of the invention that are regarded as novel, it is believed that the invention will be better understood from a consideration of the description in conjunction with the drawings. As required, detailed embodiments of the present invention are disclosed herein; however, it is to be understood that the disclosed embodiments are merely exemplary of the invention which can be embodied in various forms. Therefore, specific structural and functional details disclosed herein are not to be interpreted as limiting, but merely as a basis for the claims and as a representative basis for teaching one skilled in the art to variously employ the inventive arrangements in virtually any appropriately detailed structure. Further, the terms and phrases used herein are not intended to be limiting but rather to provide an understandable description of the invention.

### Definitions

As described herein, a “unit” means a series of identified physical components which are linked together and/or function together to perform a specified function.

As described throughout this document, the term “about” “approximately” “substantially” and “generally” shall be used interchangeably to describe a feature, shape, or measurement of a component within a tolerance such as, for example, manufacturing tolerances, measurement tolerances or the like.

As described herein, the term “removably secured,” and derivatives thereof shall be used to describe a situation wherein two or more objects are joined together in a non-permanent manner so as to allow the same objects to be repeatedly joined and separated.

As described throughout this document, the term “complementary shape,” and “complementary dimension,” shall be used to describe a shape and size of a component that is identical to, or substantially identical to the shape and size of another identified component within a tolerance such as, for example, manufacturing tolerances, measurement tolerances or the like.

As described herein, the term “large-screen LED display” describes a plurality of individual LED screens that are secured together vertically and horizontally to form a single seamless display panel.

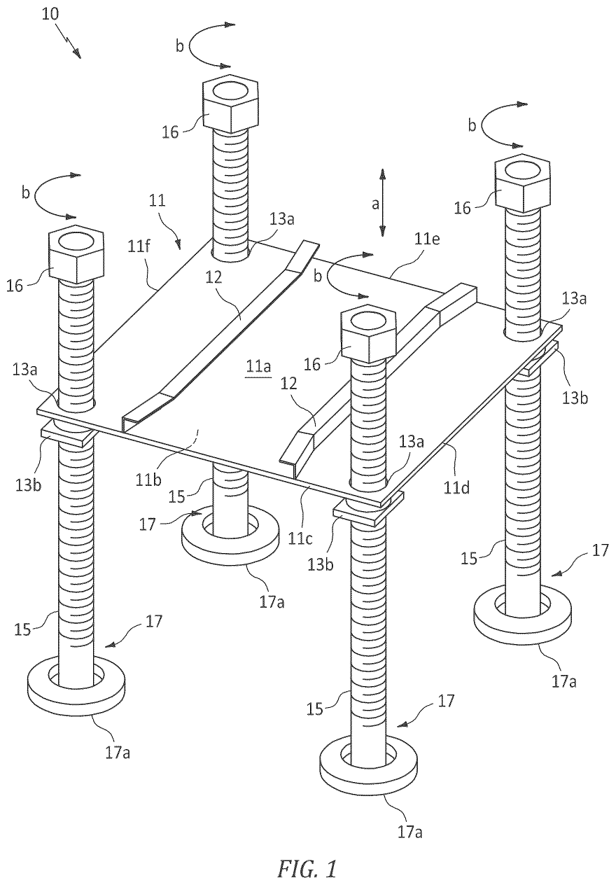

FIGS. 1-4B illustrate various embodiments and components of a ground support system that include a plurality of adjustable panel base devices 10 and/or adjustable box base devices 30 for use with an elongated beam 21 to support multiple LED screens when assembling a single large-screen LED display. In each of the drawings, identical reference numerals are used for like elements of the invention or elements of like function. For the sake of clarity, only those reference numerals are shown in the individual figures which are necessary for the description of the respective figure. For purposes of this description, the terms “upper,” “bottom,” “right,” “left,” “front,” “vertical,” “horizontal,” and derivatives thereof shall relate to the invention as oriented in FIG. 1.

FIG. 1 illustrates one embodiment of an adjustable panel base device 10 for use with the inventive system. As shown, the device can include a panel 11 having a plurality of elongated legs 15 extending therethrough.

As shown, the panel 11 can include a top surface 11a, a bottom surface 11b and a plurality of side edges 11c, 11d, 11e and 11f that form a generally square-shaped member. As will be described below, each panel can function to receive an elongated support beam 21 onto which the LED display will be positioned. As such, the panel 11 will preferably be constructed from a single piece of solid metal such as steel, or stainless steel, for example, having high tensile strength, durability, and resistance to corrosion. Of course, the panel may include any number of other shapes and sizes and may be constructed from any number of other construction materials.

In one embodiment, the panel 11 can include a pair of raised walls 12 that are positioned centrally along the top surface. In the preferred embodiment, the walls will be positioned parallel to each other and will extend across the length of the panel to form a central channel into which the elongated support beam 21 can be positioned.

Each of the walls 12 will ideally be constructed from an identical material as the panel 11 and can be welded onto the top surface or formed as an integral component with the panel itself. Additionally, each of the raised walls will include a separation distance from each other that is slightly larger than (e.g., 0.5″ to 1″) or that is complementary to the width of the support beam 21 to ensure the beam does not move or shift once placed onto the panel.

In one embodiment, a plurality of threaded receptacles can be positioned along each corner of the panel. In one embodiment, each of the threaded receptacles can include a hole 13a that extends through the panel 11, and a hollow threaded sleeve 13b that is positioned directly beneath the hole 13a to form a continuous pathway. In the preferred embodiment, the threaded sleeves 13b will be constructed from an identical material as the panel 11 and can be welded to the bottom surface 11b.

Although described above as including a specific number of threaded receptacles at a specific location, this is for illustrative purposes only. To this end, the inventive device may include any number of different holes/sleeves at any location along the panel. Additionally, other embodiments are contemplated wherein threads are positioned within the holes themselves in addition to or instead of providing the separate threaded sleeves.

In either instance, the device 10 can also include a plurality of elongated legs 15 that are positioned through each of the threaded receptacles so as to be oriented perpendicular to the panel 11. As shown, each of the legs can include, essentially, an elongated metallic rod having a plurality of threaded elements along the length thereof.

In the preferred embodiment, each of the legs will be constructed from steel or stainless steel and will have an outside diameter/cross-sectional shape and size that is complementary to the inside diameter/cross-sectional shape and size of the threaded receptacles. In this regard, the threads of each of the legs will engage the threads of each of the sleeves to cause the panel 11 to selectively move up and down the length of the legs (arrow a) when the legs are rotated (arrow b) within the holes.

In one embodiment, each of the legs 15 can include a shaped head 16 that is fixedly secured or formed along the top end of the respective leg. The shaped head can provide a gripping surface to receive a twisting force that rotates the leg 15 within the shaped receptacle. In one embodiment, the shaped head can include a square or hexagonal shape which can be engaged by a wrench or socket to receive the twisting force. Of course, the shaped head can be formed into any number of other shapes for permitting the leg to receive a twisting force from any other type of tool and/or the hand of a user.

In one embodiment, each of the legs 15 can include a base plate 17 that is positioned along the bottom end. In the preferred embodiment, the base plate can include a flat bottom surface 17a having an outside diameter that is at least 2-3 dimes greater than the outside diameter of the leg 15 to which it is attached so as to distribute the weight of the device 10 across a greater area of the ground. In one embodiment, the bottom surface of the base plate can rotate relative to the leg to which it is attached via a joint or other such component to ensure the bottom surface does not rotate or otherwise move as each the leg 15 is rotated to adjust the height of the panel 11.

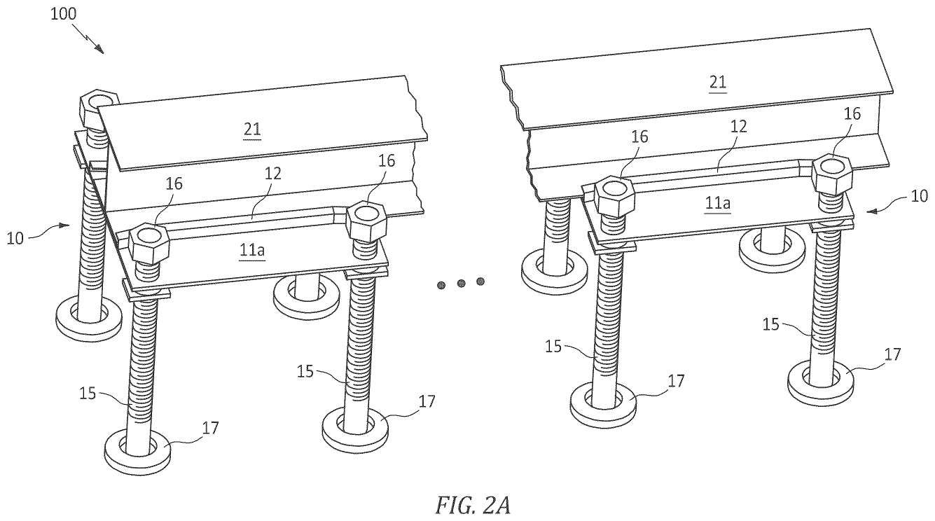

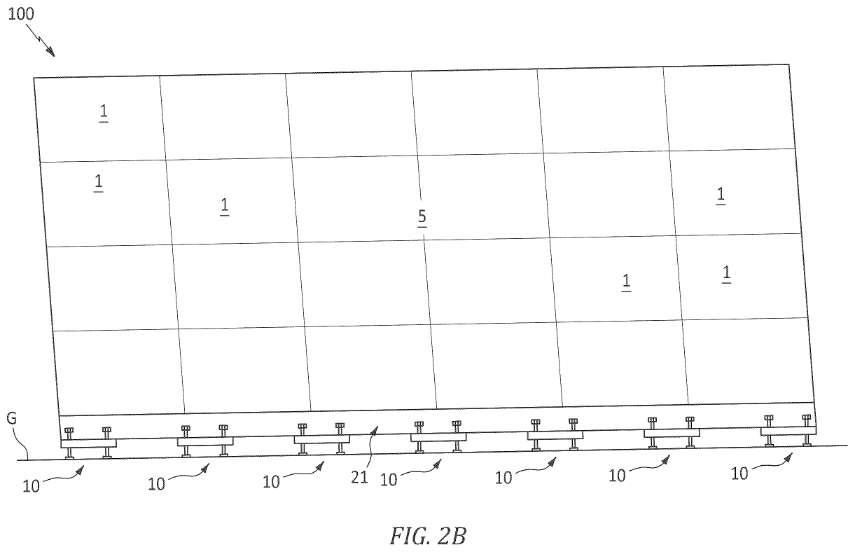

FIGS. 2A and 2B illustrate one embodiment of a ground support system 100 utilizing a plurality of the ground support devices 10 in operation.

As shown, any number of ground support devices 10 can be set up at a location where a large-screen display is to be assembled. The devices can be positioned such that the raised walls 12 of each panel are aligned serially to form a continuous pathway for receiving an elongated support beam 21 such as the illustrated steel I-beam, onto the top surface 11a of each of the aligned panels.

When so positioned, an installer can selectively rotate the heads 16 of each leg 15 of each device to raise and lower each corner of the panel. In this regard, each panel can be adjusted to be completely level in each of a front to back, and side to side manner through individual adjustments of the respective legs, and the height of each panel can be adjusted to be a uniform height to each of the other panels of the system by adjusting all of the legs.

As shown at FIG. 2B, any number of individual LED screens 1 can be positioned onto the beam 21 to create the large-screen LED display 5. Although not illustrated, any number of vertical support structures and other hardware components may also be connected to the screens 1 independently of the inventive system 100.

Importantly, as the display is being constructed, one or more of the devices 10 may shift as a result of the compressive forces applied by the assembly onto the ground or carpet beneath the device. In such a situation, and due to the unique design of the system wherein the shaped heads 16 of each of the legs are above the panel 11 and remain fully accessible at all times, an installer is able to adjust the height and/or level of each panel under load. More specifically, the installer is able to selectively rotate the shaped head of each of the legs of the affected device to return or adjust the panel to a flat and level orientation without having to remove any of the LED screens 1. Such a feature is critical and advantageously eliminates the need for the installer to remove and restack LED screens multiple times during an installation procedure.

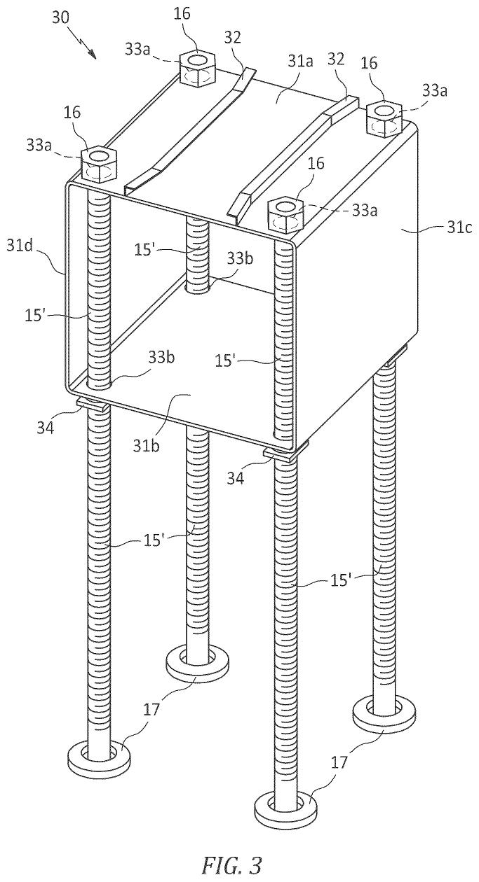

FIG. 3 illustrates one embodiment of an adjustable box base device 30 for use with the inventive system. As shown, the device 30 can include a main body 31 having an upper panel 31a, a lower panel 31b, and a pair of side walls 31c and 31d that form a hollow box-shaped body. In the preferred embodiment, the main body 31 will be constructed from a durable metal such as steel, or stainless steel having high tensile strength, durability, and resistance to corrosion. Of course, the main body may include any number of other shapes and sizes and may be constructed from any number of other construction materials.

In one embodiment, a pair of raised walls 32 can be positioned centrally along the top surface of the upper panel 31a. Raised walls 32 can be substantially identical in shape, size and function as the walls 12 described above, and function to receive and engage a support beam 21 to ensure the beam does not move or shift once placed onto the main body 31.

In one embodiment, a plurality of holes 33a and 33b can be positioned along each corner of the upper and lower panels 31a and 31b, respectively. Additionally, a plurality of hollow threaded sleeves 34 can be positioned along the bottom surface of the lower panel 31b at locations directly beneath the holes 33b. Each of the holes 33a, 33b and sleeve 34 (referred to hereinafter as cumulatively as a threaded receptacle) on each corner of the main body can be aligned serially to form a continuous pathway for receiving an elongated leg 15′.

Although described above as including a specific number of holes and/or threaded sleeves at specific locations along the main body, this is for illustrative purposes only. To this end, the inventive device may include any number of different holes/sleeves at any location along the panel. Additionally, other embodiments are contemplated wherein threads are positioned within the holes themselves in addition to or instead of providing the separate threaded sleeves. Likewise, threaded sleeves may also be positioned along the top panel 31a to be used in conjunction with the threaded sleeves 34 or instead of the same.

In either instance, the device 30 can also receive and engage a plurality of elongated legs 15′. Each leg 15′ being substantially identical to the legs 15 described above but longer in length. Each of the legs 15′ can also include a head 16 and base plate 17 as described above. As shown, each of the legs can be positioned through one set of aligned holes 33a/33b and sleeve 34 on each corner of the main body 31 so as to be oriented perpendicular to the panels 31a and 31b. Each of the legs 15′ can operate as described above to cause the main body 31 to be selectively moved up and down the length of the legs upon receiving a twisting force via the shaped head 16.

By providing two sets of aligned holes through which each leg is positioned, the system 30 increases the contact area between the respective components, thus allowing longer legs 15′ to be utilized and thereby increasing the stability of the device with regard to tortional forces. Likewise, the shape of the main body 31 further increases the height at which a support beam can be positioned, thus increasing the height of a display panel being constructed.

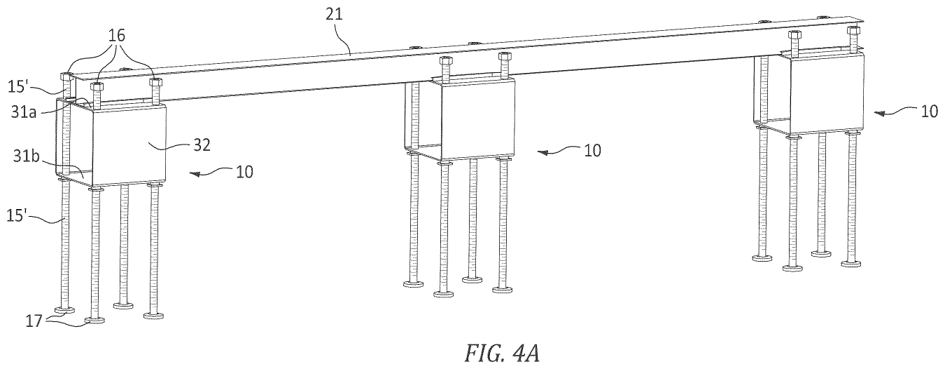

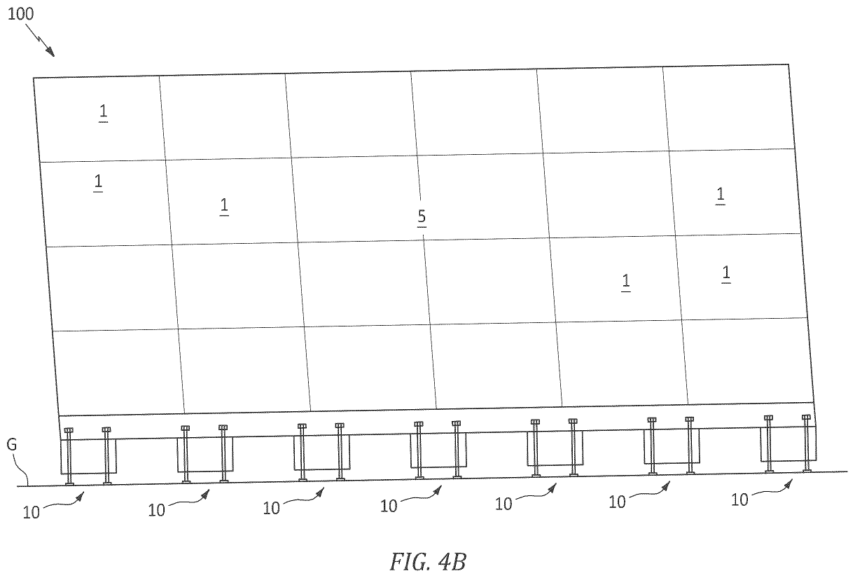

FIGS. 4A and 4B illustrate one embodiment of the system 100 utilizing the adjustable box support devices 30. As shown, devices 30 can function in a substantially identical fashion as the devices 10 described above wherein the raised walls 32 of each of the devices 30 are aligned serially to form a continuous pathway for receiving an elongated support beam 21. When so positioned, each of the legs 15′ of each device 30 can be adjusted to orient the top surface of each device in a completely level (i.e., front to back, and side to side) manner, and at a uniform height to each of the other devices of the system.

In this regard, any number of individual LED screens 1 can be positioned onto the beam 21 to create the large-screen LED display 5 which can be positioned at a greater height from the ground G. As with the system 10, the shaped heads 16 of each of the legs are above the upper panel 31 and remain fully accessible at all times, allowing an installer to adjust the height and/or level of each device under load and without having to remove any of the LED screens 1. Such a feature is critical and advantageously eliminates the need for the installer to remove and restack LED screens multiple times during an installation procedure.

Although dimensions are not critical, in the preferred embodiment each of the legs 15 for use with the device 10 can include a height of about 1 foot. Such a feature allowing each device 10 to position a support beam 21 anywhere between about 8 inches and 1 foot from the ground when assembling a large screen LED display.

Likewise, in the preferred embodiment, the main body 31 can include a thickness (e.g., distance between the upper panel 31a and the lower panel 31b) of about 1 foot, and each of the legs 15′ can include a height of about 3 feet. Such a feature allowing each device 30 to position a support beam 21 anywhere between about 3 feet and 4 feet from the ground when assembling a large screen LED display.

As to a further description of the manner and use of the present invention, the same should be apparent from the above description. Accordingly, no further discussion relating to the manner of usage and operation will be provided.

As described herein, one or more elements of the device 10 and/or 30 can each be secured together utilizing any number of known attachment means such as, for example, screws, glue, compression fittings and welds, among others. Moreover, although the above embodiments have been described as including separate individual elements, the inventive concepts disclosed herein are not so limiting. To this end, one of skill in the art will recognize that one or more individually identified elements may be formed together as one or more continuous elements, either through manufacturing processes, such as welding, casting, or molding, or through the use of a singular piece of material milled or machined with the aforementioned components forming identifiable sections thereof.

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Likewise, the term “consisting” shall be used to describe only those components identified. In each instance where a device comprises certain elements, it will inherently consist of each of those identified elements as well.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A ground support device, comprising:
at least one panel body having a top surface, a bottom surface and a plurality of edges;
a plurality of threaded receptacles that are disposed along the at least one panel body; and
a plurality of elongated legs,
wherein one of the plurality of elongated legs is positioned within each one of the plurality of threaded receptacles, and
wherein the at least one panel body is configured to move along a height of each of the plurality of elongated legs.

2. The device of claim 1, further comprising:
a pair of raised walls that are positioned along the top surface of the at least one panel body.

3. The device of claim 2, wherein the pair of raised walls are positioned parallel to each other and are configured to immobilize a support beam that is positioned on the top surface of the at least one panel body.

4. The device of claim 1, wherein each of the plurality of elongated legs includes a series of threads along an outside surface.

5. The device of claim 4, wherein each of the elongated legs are configured to rotate independently to selectively raise and lower the at least one panel body.

6. The device of claim 1, wherein each of the plurality of legs include a base plate along a bottom end.

7. A ground support system, comprising:
a plurality of ground support devices, each device including a panel body having a top surface, a bottom surface and a plurality of edges; a plurality of threaded receptacles that are disposed along the panel body; and a plurality of elongated legs that are positionable through the plurality of elongated legs; and
an elongated support beam,
wherein each of the plurality of ground support devices are configured to be aligned serially and wherein the elongated beam is configured to be suspended across the plurality of aligned ground support devices.

8. The system of claim 7, further comprising:
a pair of raised walls that are positioned along the top surface of the panel body of each of the plurality of ground support devices.

9. The system of claim 8, wherein the raised walls of each ground support device are positioned parallel to each other and are each configured to immobilize the support beam that is suspended across the plurality of aligned ground support devices.

10. The system of claim 7, wherein each of the plurality of elongated legs includes a series of threads along an outside surface.

11. The system of claim 10, wherein each of the elongated legs are configured to rotate independently to selectively raise and lower the panel body of the ground support device to which the respective leg is secured.

12. The system of claim 11, wherein each of the plurality of legs include a base plate along a bottom end.
